(19) United States
(12) Patent Application Publication
(10) Pub. No.: US 2024/0321562 A1
(43) Pub. Date: Sep. 26, 2024

(54) PLASMA PROCESSING METHOD AND PLASMA PROCESSING APPARATUS

(71) Applicant: Tokyo Electron Limited, Tokyo (JP)

(72) Inventors: Koki MUKAIYAMA, Miyagi (JP); Maju TOMURA, Miyagi (JP); Yoshihide KIHARA, Miyagi (JP); Nobuyuki FUKUI, Miyagi (JP)

(73) Assignee: Tokyo Electron Limited, Tokyo (JP)

(21) Appl. No.: 18/680,297

(22) Filed: May 31, 2024

Related U.S. Application Data
(63) Continuation of application No. PCT/JP2022/043903, filed on Nov. 29, 2022.

(30) Foreign Application Priority Data
Dec. 3, 2021 (JP) 2021-196758

(51) Int. Cl. H01J 37/32

(52) U.S. Cl. CPC H01J 37/32724; H01J 37/32119; H01J 37/32174; H01J 37/32935; H01J 2237/3341; H01J 2237/3346

(57) ABSTRACT

A plasma processing method includes: (a) providing a substrate on a substrate support in a chamber; (b) supplying a coolant to control a temperature of the substrate support; (c) supplying a processing gas into the chamber; and (d) in a state where (b) is being performed, generating plasma from the processing gas in the chamber by a source RF signal, and supplying a bias signal to etch the carbon-containing film. In (d), the coolant of (b) is set such that the substrate or the substrate support reaches a target temperature of −70° C. to 100° C. during plasma etching, the source RF signal in (d) is an RF signal having a power of 2 kW or more, and the bias signal in (d) is a bias RF signal having a power of 2 kW or more or a bias DC signal including a voltage pulse of 2 kV or more.

### CROSS-REFERENCE TO RELATED APPLICATIONS

This application is a continuation application of International Patent Application No. PCT/JP2022/043903, filed on Nov. 29, 2022, which claims priority from Japanese Patent Application No. 2021-196758, filed on Dec. 3, 2021, all of which are incorporated herein in their entireties by reference.

### TECHNICAL FIELD

The present disclosure relates to a plasma processing method and a plasma processing apparatus.

### BACKGROUND

A technology for improving the shape of a recess formed by an etching is described in Japanese Patent Laid-Open Publication No. 2015-012178.

### SUMMARY

An embodiment of the present disclosure provides a plasma processing method performed in an inductively coupled plasma processing apparatus including a chamber. The plasma processing method includes: (a) providing a substrate having a carbon-containing film and a silicon-containing mask formed on the carbon-containing film, on a substrate support in the chamber; (b) supplying a coolant to the substrate support to control a temperature of the substrate support; (c) supplying a processing gas into the chamber; and (d) in a state where (b) is being performed, generating a plasma from the processing gas in the chamber by a source RF signal, and supplying a bias signal to the substrate support to etch the carbon-containing film. In (d), the coolant of (b) is set such that the substrate or the substrate support reaches a target temperature of −70° C. or higher and 100° C. or lower during a plasma etching, the source RF signal in (d) is an RF signal having a power of 2 kW or more, and the bias signal in (d) is a bias RF signal having a power of 2 kW or more or a bias DC signal including a voltage pulse of 2 kV or more.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a configuration of a plasma processing apparatus.

FIG. 2 is a flowchart illustrating an example of a main process of a plasma processing method of the present disclosure.

FIG. 3A is a schematic view illustrating an example of a cross-section of a film structure of an etched substrate.

FIG. 3B is a schematic view illustrating an example of a cross-section of a film structure of an etched substrate.

FIG. 4 is a view illustrating examples of etching target films etched under conditions A and B.

FIG. 5 is a view schematically illustrating an example of a configuration of a plasma processing apparatus.

FIG. 6 is a flowchart illustrating an example of a plasma generation process.

FIG. 7 is a view illustrating an example of a relationship between a substrate temperature and an etching shape.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, each embodiment of the present disclosure will be described.

An embodiment of the present disclosure provides a plasma processing method performed in an inductively coupled plasma processing apparatus including a chamber. The plasma processing method includes: (a) providing a substrate having a carbon-containing film and a silicon-containing mask formed on the carbon-containing film, on a substrate support in the chamber; (b) supplying a coolant to the substrate support to control a temperature of the substrate support; (c) supplying a processing gas into the chamber; and (d) in a state where (b) is being performed, generating a plasma from the processing gas in the chamber by a source RF signal, and supplying a bias signal to the substrate support to etch the carbon-containing film. In (d), the coolant of (b) is set such that the substrate or the substrate support reaches a target temperature of −70° C. or higher and 100° C. or lower during a plasma etching, the source RF signal in (d) is an RF signal having a power of 2 kW or more, and the bias signal in (d) is a bias RF signal having a power of 2 kW or more or a bias DC signal including a voltage pulse of 2 kV or more.

In an embodiment, the plasma processing method further includes: (e) measuring a temperature of at least one of the substrate and the substrate support by a temperature sensor; and (f) controlling at least one of the source RF signal in (d), the bias signal in (d), and a set temperature of the coolant in (b) based on the temperature measured in (e), to adjust the temperature of at least one of the substrate and the substrate support.

In an embodiment, (d) includes (d1) adjusting the temperature of at least one of the substrate and the substrate support to a first temperature, and (d2) adjusting the temperature of at least one of the substrate and the substrate support to a second temperature higher than the first temperature. In this embodiment, any of (d1) and (d2) may be performed first.

In an embodiment, (d1) and (d2) are performed in this order.

In an embodiment, (d) further includes alternately repeating (d1) and (d2).

In an embodiment, (d1) and (d2) include at least one of (g), (h), (i), (j), and (k): (g) in (d1), supplying a bias signal of a first output to the substrate support, and in (d2), supplying a bias signal of a second output larger than the first output to the substrate support, (h) in (d1), supplying a bias signal of a first duty ratio to the substrate support, and in (d2), supplying a bias signal of a second duty ratio larger than the first duty ratio to the substrate support, (i) in (d1), supplying a bias signal of a first frequency to the substrate support, and in (d2), supplying a bias signal of a second frequency lower than the first frequency to the substrate support, (j) in (d1), supplying a heat transfer gas of a first pressure between the substrate and the substrate support, and in (d2), supplying a heat transfer gas of a second pressure lower than the first pressure between the substrate and the substrate support, and (k) in (d1), setting a temperature of the coolant to the first temperature, and in (d2), setting the temperature of the coolant to the second temperature higher than the first temperature.

In an embodiment, the processing gas includes an oxygen-containing gas and a sulfur-containing gas.

In an embodiment, the source RF signal has a frequency of 13 MHz or higher.

In an embodiment, the bias RF signal has a frequency of 13 MHz or lower.

In an embodiment, the carbon-containing film includes an amorphous carbon film.

In an embodiment, the silicon-containing mask includes a silicon oxynitride film.

In an embodiment, the source RF signal has a power of 4 kW or more and 30 kW or less.

In an embodiment, the bias signal has a power of 4 kW or more and 30 kW or less.

In an embodiment, the bias signal is a bias DC signal including a voltage pulse of 3 kV or more and 20 kV or less.

Another embodiment of the present disclosure provides an inductively coupled plasma processing apparatus including: a chamber; a substrate support provided in the chamber, and supporting a substrate having a carbon-containing film and a silicon-containing mask formed on the carbon-containing film; a temperature regulator that regulates a temperature of the substrate support by supplying a coolant to the substrate support; a processing gas supply that supplies a processing gas into the chamber; a source RF signal generator that generates a source RF signal; a bias signal supply that supplies a bias signal to the substrate support; and a controller. The controller performs a control for performing (a), (b), (c), and (d): (a) providing the substrate on the substrate support in the chamber, (b) in a state of (a), supplying the coolant to the substrate support to control the temperature of the substrate support by the temperature regulator, (c) supplying the processing gas into the chamber by the processing gas supply, and (d) in a state where (b) is being performed, generating a plasma from the processing gas in the chamber by a source RF signal generated by the source RF signal generator, and supplying a bias signal to the substrate support by the bias signal supply, to etch the carbon-containing film. In (d), the coolant of (b) is set such that the substrate or the substrate support reaches a target temperature of −70° C. or higher and 100° C. or lower during a plasma etching, the source RF signal in (d) is an RF signal having a power of 2 kW or more, and the bias signal in (d) is a bias RF signal having a power of 2 kW or more or a bias DC signal including a voltage pulse of 2 kV or more.

In an embodiment, the plasma processing apparatus further includes a temperature sensor capable of measuring a temperature of the substrate on the substrate support in a non-contact manner.

In an embodiment, the temperature sensor is disposed on a dielectric window that makes up the chamber.

Hereinafter, each embodiment of the present disclosure will be described in detail with reference to the drawings. In the respective drawings, the same or similar components will be denoted with the same reference numerals, and overlapping descriptions will be omitted. Unless otherwise specified, the positional relationship such as up, down, left, and right will be described based on the positional relationship illustrated in the drawings. The dimensional proportions in the drawings are not actual proportions, and the actual proportions are not limited to those illustrated in the drawings.

### Configuration of Plasma Processing Apparatus 1

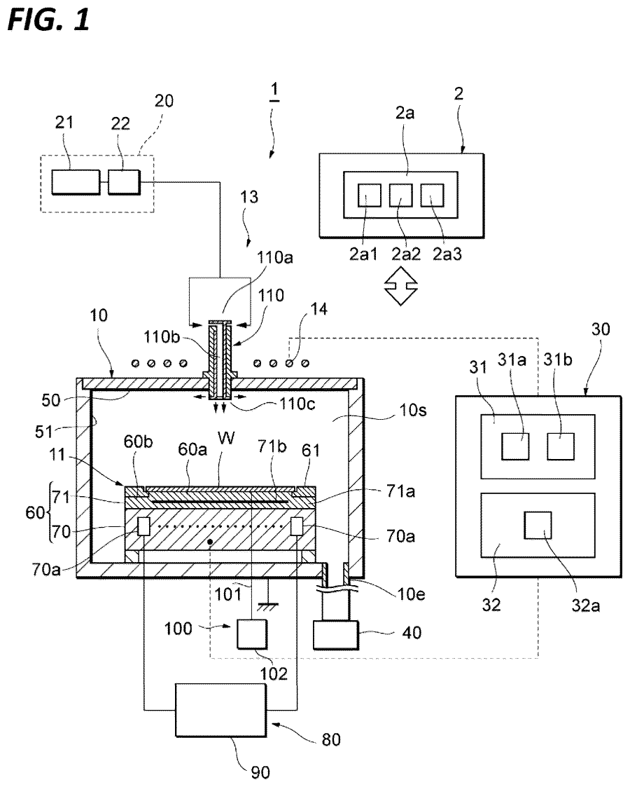

An example of a configuration of a plasma processing system will be described hereinafter. FIG. 1 is a view illustrating an example of a configuration of an inductively coupled plasma processing apparatus 1. A plasma processing method according to an embodiment (hereinafter, referred to as the “present plasma processing method”) is performed using the plasma processing apparatus 1.

The plasma processing system includes the inductively coupled plasma processing apparatus 1 and a control unit 2. The inductively coupled plasma processing apparatus 1 includes a plasma processing chamber 10, a gas supply unit 20, a power supply 30, and an exhaust system 40. The plasma processing chamber 10 includes a dielectric window 50. Further, the plasma processing apparatus 1 includes a substrate support unit 11, a gas introduction unit 13, and an antenna 14. The substrate support unit 11 is disposed inside the plasma processing chamber 10. The antenna 14 is an example of an inductively coupled plasma (ICP) source. The antenna 14 is disposed on or above the plasma processing chamber 10 (i.e., on or above the dielectric window 50). The plasma processing chamber 10 has a plasma processing space 10s defined by the dielectric window 50, the side wall 51 of the plasma processing chamber 10, and the substrate support unit 11. The plasma processing chamber 10 includes at least one gas supply port for supplying at least one processing gas to the plasma processing space 10s and at least one gas discharge port for discharging a gas from the plasma processing space. The plasma processing chamber 10 is grounded.

The substrate support unit 11 includes a main body 60 and a ring assembly 61. The main body 60 has a central region 60a for supporting a substrate W and an annular region 60b for supporting the ring assembly 61. A wafer is an example of the substrate W. The annular region 60b of the main body 60 surrounds the central region 60a of the main body 60 in plan view. The substrate W is placed on the central region 60a of the main body 60, and the ring assembly 61 is disposed on the annular region 60b of the main body 60 to surround the substrate W on the central region 60a of the main body 60. Thus, the central region 60a is also referred to as a substrate support surface for supporting the substrate W thereon, and the annular region 60b is also referred to as a ring support surface for supporting the ring assembly 61 thereon.

In an embodiment, the main body 60 includes a base 70 and an electrostatic chuck 71. The base 70 includes a conductive member. The conductive member of the base 70 may function as a bias electrode. The electrostatic chuck 71 is disposed on the base 70. The electrostatic chuck 71 includes a ceramic member 71a and an electrostatic electrode 71b disposed inside the ceramic member 71a. The ceramic member 71a has the central region 60a. In an embodiment, the ceramic member 71a also has the annular region 60b. Further, another member surrounding the electrostatic chuck 71, such as an annular electrostatic chuck or an annular insulating member, may have the annular region 60b. In this case, the ring assembly 61 may be disposed on the annular electrostatic chuck or the annular insulating member, or on both the electrostatic chuck 71 and the annular insulating member. Further, an RF or DC electrode may be disposed inside the ceramic member 71a, and in this case, the RF or DC electrode functions as a bias electrode. Further, both the conductive member of the base 70 and the RF or DC electrode may function as two bias electrodes.

The ring assembly 61 includes one or more annular members. In an embodiment, the one or more annular members include one or more edge rings and at least one covering ring. The edge rings are formed of a conductive or insulating material, and the covering ring is formed of an insulating material.

The substrate support unit 11 may further include a temperature adjustment module configured to adjust at least one of the electrostatic chuck 71, the ring assembly 61, and the substrate to a target temperature. The temperature adjustment module may include a heater, a heat transfer medium, a flow path 70a, or a combination thereof. A heat transfer fluid, such as brine or gas, flows in the flow path 70a. In an embodiment, the flow path 70a is formed in the base 70, and one or more heaters are disposed in the ceramic member 71a of the electrostatic chuck 71.

A temperature regulation unit 80 is an example of the temperature adjustment module. In an embodiment, the temperature regulation unit 80 includes the flow path 70a and a coolant circulator 90 connected to the flow path 70a. The coolant circulator 90 may set a coolant to a predetermined temperature, and supply the coolant to the flow path 70a to circulate the coolant in the flow path 70a. In an embodiment, the coolant circulator 90 may set the temperature of the coolant to −50° C. or lower. Setting the temperature of the coolant includes not only setting the temperature of the coolant to the set temperature, but also setting the temperature in the coolant circulator 90 such that the coolant reaches the set temperature. The temperature regulation unit 80 may supply the coolant with the temperature set in the coolant circulator 90 to the substrate support unit 11 through the flow path 70a, so as to regulate the temperature of the substrate support unit 11.

The substrate support unit 11 may further include a heat transfer gas supply unit 100 configured to supply a heat transfer gas between the back surface of the substrate W and the central region 60a. In an embodiment, the heat transfer gas supply unit 100 includes a gas supply line 101 provided in the substrate support unit 11. The gas supply line 101 supplies a heat transfer gas (e.g., He gas) from a heat transfer gas supply mechanism 102 to the gap between the upper surface of the electrostatic chuck 71 and the back surface of the substrate W. The heat transfer gas supply unit 100 may supply a heat transfer gas with a predetermined pressure.

The substrate support unit 11 is provided with lifters (lift pins) (not illustrated). In an embodiment, the lifters are arranged in a plurality of through holes that passes through the substrate support unit 11 in the vertical direction, and move in the through holes in the vertical direction by a driving device (not illustrated). In an embodiment, the substrate W is carried into/out of the chamber 10 by a transfer arm (not illustrated). The lifters may move the substrate W while supporting the substrate W on the substrate support unit 11, exchange the substrate W with respect to the transfer arm, and place the substrate W on the substrate support unit 11.

The gas introduction unit 13 is configured to introduce at least one processing gas from the gas supply unit 20 into the plasma processing space 10s. The gas introduction unit 13 is an example of a processing gas supply unit. In an embodiment, the gas introduction unit 13 includes a center gas injector (CGI) 110. The center gas injector 110 is disposed above the substrate support unit 11, and attached to a central opening formed in the dielectric window 50. The center gas injector 110 includes at least one gas supply port 110a, at least one gas flow path 110b, and at least one gas introduction port 110c. A processing gas supplied to the gas supply port 110a passes through the gas flow path 110b and is introduced into the plasma processing space 10s from the gas introduction port 110c. In an embodiment, the processing gas includes an oxygen-containing gas (e.g., a gas containing O₂) and a sulfur-containing gas (e.g., a gas containing COS). Further, the gas introduction unit 13 may include one or more side gas injectors (SGI) attached to one or more openings formed in the side wall 51, in addition to or instead of the center gas injector 110.

The gas supply unit 20 may include at least one gas source 21 and at least one flow controller 22. In an embodiment, the gas supply unit 20 is configured to supply at least one processing gas from each corresponding gas source 21 to the gas introduction unit 13 via each corresponding flow controller 22. Each flow controller 22 may include, for example, a mass flow controller or a pressure-controlled flow controller. The gas supply unit 20 may include one or more flow modulation devices that modulate or pulse the flow of at least one processing gas. The gas supply unit 20 may be included in a portion of the gas introduction unit 13.

The power supply 30 includes an RF (radio-frequency) power supply 31 coupled to the plasma processing chamber 10 via at least one impedance matching circuit. The

RF power supply 31 is configured to supply at least one RF signal (RF power), such as a source RF signal and a bias RF signal, to at least one bias electrode and the antenna 14. As a result, plasma is formed from at least one processing gas supplied to the plasma processing space 10s. Thus, the RF power supply 31 may function as at least a portion of a plasma generation unit configured to generate plasma from one or more processing gases in the plasma processing chamber 10. When the bias RF signal is supplied to at least one bias electrode, a bias potential may be generated on the substrate W, and ions in the formed plasma may be attracted to the substrate W.

In an embodiment, the RF power supply 31 includes a first RF generation unit 31a and a second RF generation unit 31b. The first RF generation unit 31a is an example of a source RF signal generation unit that generates the source RF signal. The first RF generation unit 31a is coupled to the antenna 14, and configured to generate the source RF signal (source RF power) for plasma generation via at least one impedance matching circuit. In an embodiment, the source RF signal has a frequency in the range of 10 MHz to 150 MHz. In an embodiment, the source RF signal has a frequency of 13 MHz or higher. The source RF power has a power of 2 kW or higher. In an embodiment, the first RF generation unit 31a may be configured to generate a plurality of source RF signals having different frequencies. The generated one or more source RF signals are supplied to the antenna 14.

The second RF generation unit 31b is an example of a bias signal supply unit that supplies a bias signal, which is the bias RF signal, to the substrate support unit 11. The second RF generation unit 31b is coupled to at least one bias electrode of the substrate support unit 11 via at least one impedance matching circuit, and configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHz. In an embodiment, the bias RF signal has a frequency of 13 MHz or lower. The bias RF signal includes a bias RF signal having a power of 2 kW or higher. In an embodiment, the second RF generation unit 31b may be configured to generate a plurality of bias RF signals having different frequencies. The generated one or more bias RF signals are supplied to at least one bias electrode. In various embodiments, at least one of the source RF signal and the bias RF signal may be pulsed.

The power supply 30 may include a DC power supply 32 coupled to the plasma processing chamber 10. The DC power supply 32 includes a bias DC generation unit 32a. The bias DC generation unit 32a is an example of a bias signal supply unit that supplies a bias signal, which is a bias DC signal including a voltage pulse, to the substrate support unit 11. In an embodiment, the bias DC generation unit 32a is connected to at least one bias electrode of the substrate support unit 11, and configured to generate a bias DC signal (bias DC power). The generated bias DC signal is applied to at least one bias electrode.

In various embodiments, the bias DC signal may be pulsed. In an embodiment, the bias DC generation unit 32a may supply a bias DC signal including a voltage pulse of 3 kV (effective value) or more, to the substrate support unit 11. In this case, a sequence of a DC-based voltage pulse is applied to at least one bias electrode. The voltage pulse may have a rectangular, trapezoidal, or triangular pulse waveform, or a combination thereof. In an embodiment, a waveform generation unit for generating the sequence of the voltage pulse from a DC signal is connected between the bias DC generation unit 32a and at least one bias electrode. Thus, the bias DC generation unit 32a and the waveform generation unit make up a voltage pulse generation unit. The voltage pulse may have the positive or negative polarity. The sequence of the voltage pulse may include one or more positive polarity voltage pulses and one or more negative polarity voltage pulses within one cycle. The bias DC generation unit 32a may be provided in addition to the RF power supply 31, or may be provided in place of the second RF generation unit 31b.

The antenna 14 includes one or a plurality of coils. In an embodiment, the antenna 14 may include an outer coil and an inner coil, which are arranged coaxially. In this case, the RF power supply 31 may be connected to both the outer and inner coils, or may be connected to either one of the outer and inner coils. In the former case, the same RF generation unit may be connected to both the outer and inner coils, or separate RF generation units may be connected to the outer and inner coils, respectively.

The exhaust system 40 may be connected to a gas discharge port 10e formed at, for example, the bottom of the plasma processing chamber 10. The exhaust system 40 may include a pressure regulation valve and a vacuum pump. The pressure in the plasma processing space 10s is regulated by the pressure regulation valve. The vacuum pump may include a turbo molecular pump, a dry pump, or a combination thereof.

The control unit 2 processes computer-executable commands for causing the plasma processing apparatus 1 to perform various steps described herein below. The control unit 2 may be configured to control each component of the plasma processing apparatus 1 to perform the various steps described herein. In an embodiment, the control unit 2 controls, for example, the operations of the gas introduction unit, the power supply 30 (including the first RF generation unit 31a, the second RF generation unit 31b, and the bias DC generation unit 32a), the temperature regulation unit 80, the exhaust system 40, and the heat transfer gas supply unit 100. In an embodiment, a portion of the control unit 2 or the entire control unit 2 may be included in the plasma processing apparatus 1. The control unit 2 may include, for example, a computer 2a. The computer 2a may include, for example, a processing unit 2a1 (central processing unit (CPU)), a storage unit 2a2, and a communication interface 2a3. The processing unit 2a1 may be configured to read programs from the storage unit 2a2, and perform various control operations by executing the read programs. The programs may be stored in the storage unit 2a2 in advance, or may be acquired via a medium when necessary. The acquired programs are stored in the storage unit 2a2, and read from the storage unit 2a2 to be executed by the processing unit 2a1. The medium may be any of various storage media readable by the computer 2a, or may be a communication line connected to the communication interface 2a3. The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### Example of Present Plasma Processing Method

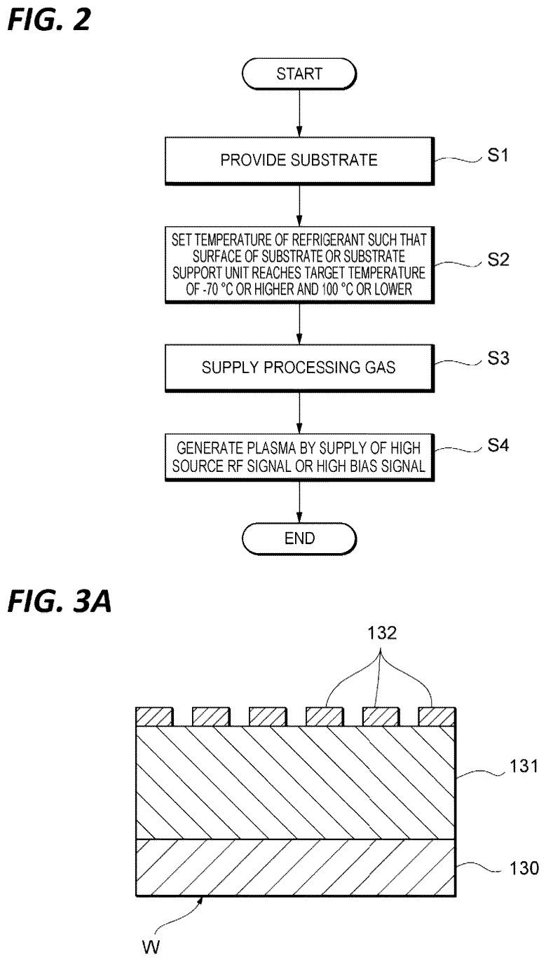

FIG. 2 is a flowchart illustrating the main process of the present plasma processing method performed in the plasma processing apparatus 1. In an embodiment, the present plasma processing method uses the inductively coupled plasma processing apparatus 1 to etch a substrate W having a carbon-containing film (organic film) and a silicon-containing mask formed on the carbon-containing film. In an embodiment, the present plasma processing method includes performing a processing of a deep hole with a high aspect ratio (ratio of the depth of a processing recess to the width thereof (depth/width)) of 30 or more.

First, in an embodiment, a substrate W having a base film 130, a carbon-containing film 131, and a silicon-containing mask 132 is prepared as illustrated in FIG.

3A. An example of the carbon-containing film 131 is an amorphous carbon film. An example of the silicon-containing mask 132 is a SiON mask. The substrate W is carried into the chamber 10 by a transfer arm, placed on the substrate support unit 11 by the lifters, and held by adsorption on the substrate support unit 11. As a result, the substrate W is provided on the substrate support unit 11 as illustrated in FIG. 1 (step S1 in FIG. 2). The carbon-containing film 131 and the silicon-containing mask 132 may be formed on the substrate W in the chamber 10.

Then, in the coolant circulator 90, the coolant is set such that the substrate W or the substrate support unit 11 reaches a target temperature of −70° C. or higher and 100° C. or lower during a plasma etching. As an example, the coolant is set to a predetermined temperature (cryogenic) of −50° C. or lower such that the surface of the substrate support unit 11 reaches the target temperature above. The coolant is supplied from the coolant circulator 90 to the flow path 70a, and the temperature of the substrate support unit 11 is controlled by the coolant (step S2 in FIG. 2). The timing at which the coolant begins to be supplied to the substrate support unit 11 is not limited to the timing after the substrate W is provided on the substrate support unit 11, but may be a timing before the substrate W is provided on the substrate support unit 11 or simultaneously with the time when the substrate W is provided on the substrate support unit 11.

In the state where the temperature of the substrate support unit 11 is controlled by the coolant, a processing gas is supplied to the processing space 10s of the chamber 10 by the gas introduction unit 13 (step S3 in FIG. 2). In an embodiment, the processing gas includes an oxygen-containing gas (e.g., a gas containing O₂) and a sulfur-containing gas (e.g., a gas containing COS) for etching the carbon-containing film 131.

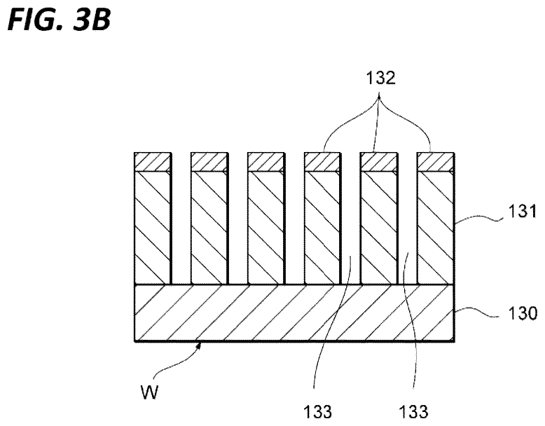

Next, in an embodiment, a source RF signal is supplied to the antenna 14 by the first RF generation unit 31a, and plasma is generated from the processing gas in the chamber 10 by the source RF signal. Further, a bias signal is supplied to the substrate support unit 11 by the second RF generation unit 31b (step S4 (plasma generation step S4) in FIG. 2). The plasma generation step S4 is performed in the state where the temperature of the substrate support unit 11 is controlled by the cryogenic coolant. As a result, in an embodiment, the carbon-containing film 131 of the substrate W is etched so that a recess 133 is formed as illustrated in FIG. 3B. The recess 133 is an example of a processing shape of the carbon-containing film. At this time, the source RF signal is a high source RF signal with a power of 2 kW or more, and the bias signal is a high bias RF signal with a power of 2 kW or more. The source RF signal may have a power of 4 kW or more. The source RF signal may have a power of 30 kW or less. The bias signal may have a power of 4 kW or more. The bias signal may have a power of 30 kW or less.

In an embodiment, the bias signal supplied to the substrate support unit 11 may be a bias DC signal including a voltage pulse supplied by the bias DC generation unit 32a, instead of the bias RF signal supplied by the second RF generation unit 31b. In this case, the bias DC signal may include a voltage pulse of 2 kV (effective value) or more. The bias DC signal may include a voltage pulse of 3 kV or more. The bias DC signal may include a voltage pulse of 20 kV or less.

After a predetermined time elapses, for example, the supply of the source RF signal and the bias signal and the supply of the processing gas is stopped, and the etching of the carbon-containing film 131 is terminated. Then, the substrate W is moved up by the lifters, delivered to the transfer arm, and carried out of the chamber 10. Then, the present plasma processing method is ended.

According to the present embodiment, the present plasma processing method supplies the high source RF signal of 2 kW or more to the antenna 14 and the high bias RF signal having a power of 2 kW or more or the high bias DC signal including a voltage pulse of 2 kV or more to the substrate support unit 11, while controlling the temperature of the substrate support unit 11 by the coolant set such that the substrate W or the substrate support unit 11 reaches the target temperature of −70° C. or higher and 100° C. or lower during the plasma etching. Then, plasma is generated from the processing gas so that the carbon-containing film 131 is etched. As a result, a high etching rate may be achieved while improving the etching processing shape. The present plasma processing method may be a processing of a deep hole with a high aspect ratio.

### Examples

An etching process was performed using the plasma processing apparatus described above under Conditions A and B below. During the plasma etching under Conditions A and B, the temperature of the substrate or the substrate support unit was controlled by the coolant to reach the same target temperature. The etching target film was a carbon-containing film M2 with a silicon-containing mask M1 on the surface thereof.
Condition A:
Source RF signal: 2,000 W
Bias signal: 1,850 W
Coolant temperature: 0° C.
Processing time: 4 min
Condition B:
Source RF signal: 4,500 W
Bias signal: 4,000 W
Coolant temperature: −60° C.
Processing time: 4 min

Condition B satisfies the condition for the present plasma processing method.

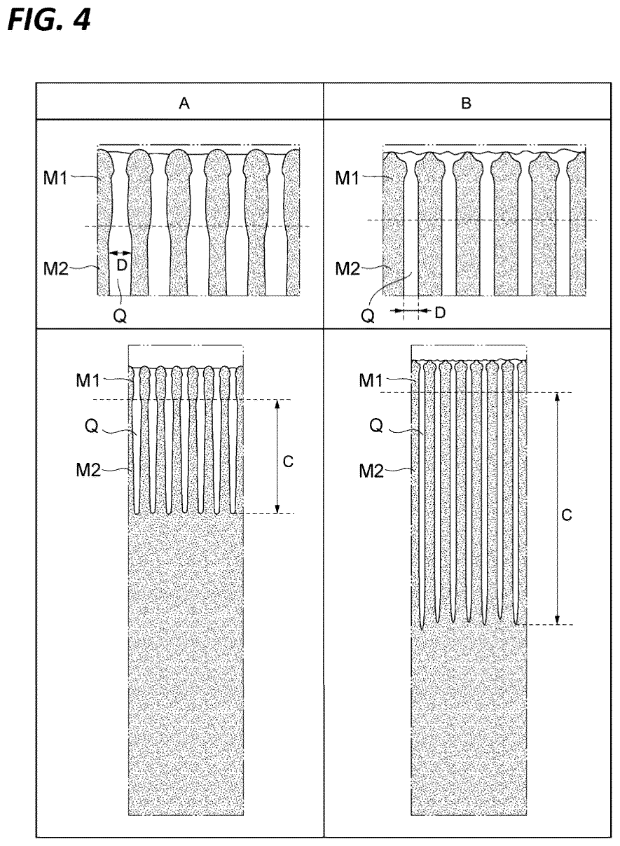

FIG. 4 is a view illustrating each of etching target films etched under Conditions A and B. The upper part of FIG. 4 represents an enlarged view of the upper portion of each etching target film, and the lower part of FIG. 4 represents an overall view of each etching target film. In the etching under Condition B, the etching depth C of a recess Q is deeper than that in the etching under Condition A, and the hole width D of the recess Q is narrower than that in the etching under Condition A. In Condition A, the etching rate is 293 nm/min, and the hole width D of the bowing portion is 95 nm. In Condition B, the etching rate is 607 nm/min, and the hole width D is 74 nm. It may be confirmed that under Condition B, the vertical shape of the recess Q is improved, and a higher etching rate is achieved.

### Other Embodiments of Present Plasma Processing Method

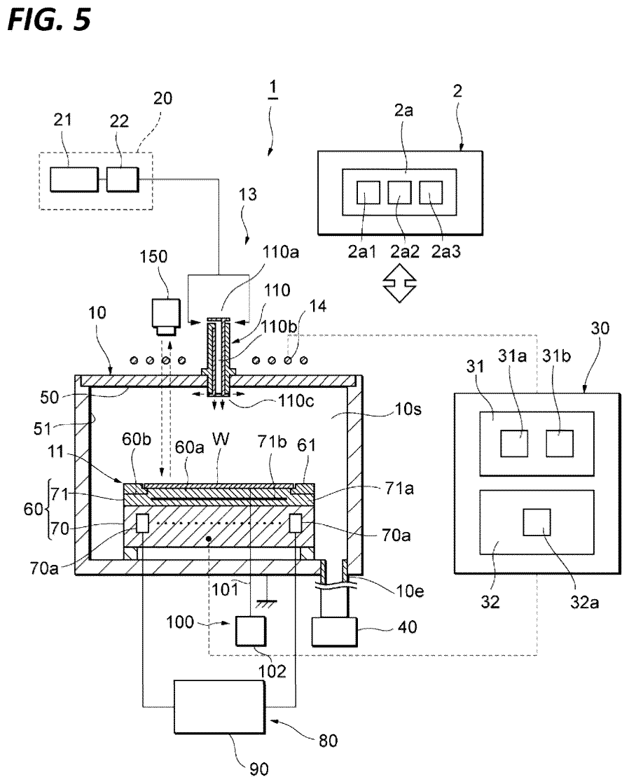

FIG. 5 is a view schematically illustrating an example of a configuration of the plasma processing apparatus 1 in which the present plasma processing method of the present embodiment is performed.

In an embodiment, the plasma processing apparatus 1 further includes a temperature sensor 150. In an embodiment, the temperature sensor 150 is an optical interference thermometer, and is disposed above the dielectric window 50. The temperature sensor 150 may measure the temperature of the substrate W in a non-contact manner by irradiating light onto the substrate W on the substrate support unit 11 and receiving the reflected light. The measurement result from the temperature sensor 150 is output to the control unit 2, and the control unit 2 may regulate the temperature of the substrate W by controlling the source RF signal supplied to the antenna 14, the bias signal supplied to the substrate support unit 11, and the set temperature of the coolant supplied to the substrate support unit 11. The other components of the plasma processing apparatus 1 are the same as described above.

In the present plasma processing method of an embodiment, the temperature of the substrate W on the substrate support unit 11 is measured by the temperature sensor 150 during the plasma generation step S4. Based on the result of the temperature measurement, at least one of the source RF signal, the bias signal, and the set temperature of the coolant is controlled. As a result, the temperature of the substrate W on the substrate support unit 11 is regulated. In an embodiment, when the temperature of the substrate W measured by the temperature sensor 150 is lower than, for example, the target temperature, the source RF signal or the bias signal is increased, so that the set temperature of the coolant increases. When the temperature of the substrate W measured by the temperature sensor 150 is higher than the target temperature, the source RF signal or the bias signal is decreased, so that the set temperature of the coolant is decreased. The target temperature of the substrate W may be calculated from the correlation among, for example, the temperature of the substrate W, the etching processing shape, and the etching rate, which is obtained in advance, may be calculated by analysis software, or may be arbitrarily determined by a user. The measurement of the temperature of the substrate W by the temperature sensor 150 may be performed continuously, intermittently, or a predetermined number of times during the plasma generation step S4. The other steps of the present plasma processing method are the same as described above.

According to the present embodiment, the temperature of the substrate W during the plasma generation step S4 becomes close to the target temperature. That is, the balance between the heat input to the substrate W by the high source RF signal or the high bias signal and the heat output by the cryogenic coolant becomes appropriate. As a result, the etching processing shape is further improved, so that a higher etching rate is achieved.

In the present embodiment, the temperature of the substrate support unit 11 may be measured by the temperature sensor 150. In this case, at least one of the source RF signal, the bias signal, and the set temperature of the coolant is controlled based on the measurement result of the temperature of the substrate support unit 11. As a result, the temperature of the substrate W on the substrate support unit 11 or the substrate support unit 11 is regulated. Further, the temperatures of both the substrate W and the substrate support unit 11 may be measured, and the temperature of the substrate W or the substrate support unit 11 may be regulated based on the measured temperatures.

### Other Embodiments of Present Plasma Processing Method

In the processing of a deep hole with a high aspect ratio, it is desirable that the hole has a bottom shape close to a perfect circle while having a sufficient vertical shape. Thus, in the present plasma processing method of the present embodiment, the temperature of at least one of the substrate W and the substrate support unit 11 is regulated in the plasma generation step S4. The temperature of the substrate W or the substrate support unit 11 depends on the amount of heat input and output to/from the substrate W (heat amount obtained by adding input heat and output heat).

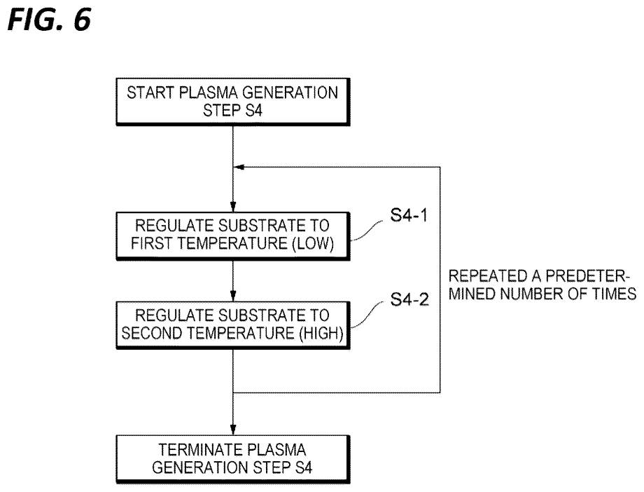

FIG. 6 is a flowchart illustrating an example of the plasma generation step of the present embodiment. In an embodiment, the plasma generation step S4 includes step S4-1 for regulating the temperature of the substrate W to a first temperature (low), and step S4-2 for regulating the temperature of the substrate W to a second temperature (high) higher than the first temperature. In an embodiment, the first temperature (low) is 40° C. or lower, and the second temperature (high) is 40° C. or higher. The regulation of the temperature of the substrate W includes not only the case where the temperature of the substrate W is actually regulated to the first temperature or the second temperature, but also the case where the temperature of the substrate W is regulated to become close to the first temperature or the second temperature. In an embodiment, instead of the temperature of the substrate W, the temperature of the substrate support unit 11 may be regulated, or the temperatures of both the substrate W and the substrate support unit 11 may be regulated. In the plasma generation step S4 of the present embodiment as well, the high source RF signal of 2 kW or more is supplied to the antenna 14, and the high bias RF signal of 2 kW or more or the high bias DC signal including a voltage pulse of 2 kV or more is supplied to the substrate support unit 11, while controlling the temperature of the substrate support unit 11 by the coolant set such that the substrate W or the substrate support unit 11 reaches the target temperature of −70° C. or higher and 100° C. or lower during the plasma etching.

As an embodiment, steps S4-1 and S4-2 are performed in this order. As an embodiment, steps S4-1 and S4-2 are repeated alternately a predetermined number of times. The predetermined number of times may be one or more times. In an embodiment, steps S4-1 and S4-2 may be performed in the reverse order, i.e., step S4-2 may be performed first, followed by step S4-1. Then, steps S4-1 and S4-2 may be repeated alternately in this order a predetermined number of times.

As an embodiment, steps S4-1 and S4-2 (the regulation of the temperature of the substrate W or the substrate support unit 11) are performed by Controls 1 to 5 below.

In step S4-1, a bias signal of a first output is supplied to the substrate support unit 11, and in step S4-2, a bias signal of a second output larger than the first output is supplied to the substrate support unit 11 (Control 1). In an embodiment, the regulation of the output of the bias signal is performed by the second RF generation unit 31b or the bias DC generation unit 32a.

In step S4-1, a bias signal of a first duty ratio is supplied to the substrate support unit 11, and in step S4-2, a bias signal of a second duty ratio larger than the first duty ratio is supplied to the substrate support unit 11 (Control 2). The second duty ratio has a higher bias signal (bias power) than that of the first duty ratio. The cycle of the pulse wave of the bias signal includes a period of a high pulse level and a period of a low pulse level. The duty ratio of the bias signal is the proportion of the period of high level in the cycle of the pulse wave. In an embodiment, the regulation of the duty ratio of the bias signal is performed by the second RF generation unit 31b or the bias DC generation unit 32a.

In step S4-1, a bias signal of a first frequency is supplied to the substrate support unit 11, and in step S4-2, a bias signal of a second frequency lower than the first frequency is supplied to the substrate support unit 11 (Control 3). In an embodiment, the regulation of the frequency of the bias signal is performed by the second RF generation unit 31b or the bias DC generation unit 32a.

In the plasma generation step S4 of an embodiment, a heat transfer gas is supplied between the substrate W and the substrate support unit 11 by the heat transfer gas supply unit 100. In step S4-1, a heat transfer gas of a first pressure is supplied between the substrate W and the substrate support unit 11, and in step S4-2, a heat transfer gas of a second pressure lower than the first pressure is supplied between the substrate W and the substrate support unit 11 (Control 4). In an embodiment, the regulation of the supply pressure of the heat transfer gas is performed by the heat transfer gas supply unit 100.

In step S4-1, the temperature of the coolant controlling the temperature of the substrate support unit 11 is set to a first temperature, and in step S4-2, the temperature of the coolant is set to a second temperature higher than the first temperature (Control 5). In an embodiment, the regulation of the set temperature of the coolant is performed by the temperature regulation unit 80.

In an embodiment, one of Controls 1 to 5 is performed. In an embodiment, a plurality of controls among Controls 1 to 5 are performed.

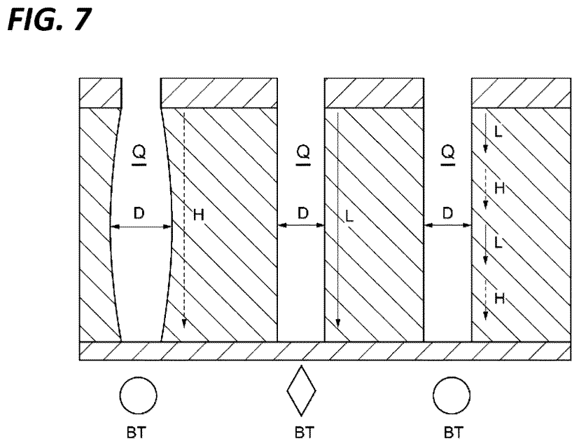

FIG. 7 is a view illustrating the relationship between the substrate temperature and the etching shape. When the plasma generation step is performed at a high temperature H where the set temperature of the substrate is constantly high (the amount of heat input and output to/from the substrate (large)), the bottom shape BT of the etched recess Q tends to become close to a perfect circle, but the widths D of some holes are widened so that the vertical shape of the recess Q tends to deteriorate. Meanwhile, when the plasma generation step is performed at a low temperature L where the set temperature of the substrate is constantly low (the amount of heat input and output to/from the substrate (small)), the widening of the hole width D tends to decrease so that the vertical shape of the hole improves, but the bottom shape BT of the recess Q tends to become out of a perfect circle. By performing the plasma generation step S4 in which the first temperature H and the second temperature L are combined as the present plasma processing method, the etched recess Q may have the bottom shape BT close to a perfect circle while having a sufficient vertical shape.

In the present embodiment, steps S4-1 and S4-2 may be each performed once without being repeated. Assuming that one set includes performing step S4-1 once and performing step S4-2 once, one set may be performed once or multiple times, and then, step S4-1 may be further performed lastly. In an embodiment, steps S4-1 and S4-2 may be performed alternately in this order, and step S4-1 may be further performed lastly.

According to an embodiment of the present disclosure, it is possible to provide a technology, which achieves a high etching rate while improving an etching processing shape.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A plasma processing method comprising:
(a) providing a substrate having a carbon-containing film and a silicon-containing mask formed on the carbon-containing film, on a substrate support in a chamber of an inductively coupled plasma processing apparatus;
(b) supplying a coolant to the substrate support to control a temperature of the substrate support;
(c) supplying a processing gas into the chamber; and
(d) in a state where (b) is being performed, generating a plasma from the processing gas in the chamber by a source RF signal, and supplying a bias signal to the substrate support to etch the carbon-containing film, wherein in (d), the coolant of (b) is set such that the substrate or the substrate support reaches a target temperature of −70° C. or higher and 100° C. or lower during a plasma etching, the source RF signal in (d) is an RF signal having a power of 2 kW or more, and the bias signal in (d) is a bias RF signal having a power of 2 kW or more or a bias DC signal including a voltage pulse of 2 kV or more.

2. The plasma processing method according to claim 1, further comprising:
(e) measuring a temperature of at least one of the substrate and the substrate support by a temperature sensor; and
(f) controlling at least one of the source RF signal in (d), the bias signal in (d), and a set temperature of the coolant in (b) based on the temperature measured in (e), to adjust the temperature of at least one of the substrate and the substrate support.

3. The plasma processing method according to claim 1, wherein (d) includes
(d1) adjusting the temperature of at least one of the substrate and the substrate support to a first temperature, and
(d2) adjusting the temperature of at least one of the substrate and the substrate support to a second temperature higher than the first temperature.

4. The plasma processing method according to claim 3, wherein (d1) and (d2) are performed in this order.

5. The plasma processing method according to claim 3, wherein (d) further includes
alternately repeating (d1) and (d2).

6. The plasma processing method according to claim 3, wherein (d1) and (d2) include at least one of (g), (h), (i), (j), and (k) below,
(g) in (d1), supplying a bias signal of a first output to the substrate support, and in (d2), supplying a bias signal of a second output larger than the first output to the substrate support,
(h) in (d1), supplying a bias signal of a first duty ratio to the substrate support, and in (d2), supplying a bias signal of a second duty ratio larger than the first duty ratio to the substrate support,
(i) in (d1), supplying a bias signal of a first frequency to the substrate support, and in (d2), supplying a bias signal of a second frequency lower than the first frequency to the substrate support,
(j) in (d1), supplying a heat transfer gas of a first pressure between the substrate and the substrate support, and in (d2), supplying a heat transfer gas of a second pressure lower than the first pressure between the substrate and the substrate support, and
(k) in (d1), setting a temperature of the coolant to the first temperature, and in (d2), setting the temperature of the coolant to the second temperature higher than the first temperature.

7. The plasma processing method according to claim 1, wherein the processing gas includes an oxygen-containing gas and a sulfur-containing gas.

8. The plasma processing method according to claim 1, wherein the source RF signal has a frequency of 13 MHz or higher.

9. The plasma processing method according to claim 1, wherein the bias RF signal has a frequency of 13 MHz or lower.

10. The plasma processing method according to claim 1, wherein the carbon-containing film includes an amorphous carbon film.

11. The plasma processing method according to claim 1, wherein the silicon-containing mask includes a silicon oxynitride film.

12. The plasma processing method according to claim 1, wherein the source RF signal has a power of 4 kW or more and 30 kW or less.

13. The plasma processing method according to claim 12, wherein the bias signal has a power of 4 kW or more and 30 kW or less.

14. The plasma processing method according to claim 1, wherein the bias signal is a bias DC signal including a voltage pulse of 3 kV or more and 20 kV or less.

15. An inductively coupled plasma processing apparatus comprising:
a chamber;
a substrate support provided in the chamber, and configured to support a substrate;
a temperature regulator configured to regulate a temperature of the substrate support by supplying a coolant to the substrate support;
a processing gas supply configured to supply a processing gas into the chamber;
a source RF signal generator configured to generate a source RF signal;
a bias signal supply configured to supply a bias signal to the substrate support; and
a processing circuitry configured to control the inductively coupled plasma processing apparatus to perform (a), (b), (c), and (d) below,
(a) providing the substrate on the substrate support in the chamber, the substrate including a carbon-containing film and a silicon-containing mask formed on the carbon-containing film,
(b) in a state of (a), supplying the coolant to the substrate support to control the temperature of the substrate support by the temperature regulator,
(c) supplying the processing gas into the chamber by the processing gas supply, and
(d) in a state where (b) is being performed, generating a plasma from the processing gas in the chamber by a source RF signal generated by the source RF signal generator, and supplying a bias signal to the substrate support by the bias signal supply, to etch the carbon-containing film,
wherein in (d), the coolant of (b) is set such that the substrate or the substrate support reaches a target temperature of −70° C. or higher and 100°° C. or lower during a plasma etching,
the source RF signal in (d) is an RF signal having a power of 2 kW or more, and
the bias signal in (d) is a bias RF signal having a power of 2 kW or more or a bias DC signal including a voltage pulse of 2 kV or more.

16. The inductively coupled plasma processing apparatus according to claim 15, further comprising a temperature sensor configured to measure a temperature of the substrate on the substrate support in a non-contact manner.

17. The inductively coupled plasma processing apparatus according to claim 16, wherein the temperature sensor is disposed on a dielectric window that makes up the chamber.
